(19) United States
(12) Patent Application Publication
(10) Pub. No.: US 2025/0192086 A1
(43) Pub. Date: Jun. 12, 2025

(54) CHIP-ON-FILM PACKAGE AND DISPLAY APPARATUS INCLUDING THE SAME

(71) Applicant: Samsung Electronics Co., Ltd., Suwon-si (KR)

(72) Inventor: Duckgyu Kim, Suwon-si (KR)

(21) Appl. No.: 18/762,045

(22) Filed: Jul. 2, 2024

(30) Foreign Application Priority Data
Dec. 11, 2023 (KR) 10-2023-0178741

(51) Int. Cl. H01L 23/00; H01L 23/31; H01L 23/36; H01L 25/16

(52) U.S. Cl. CPC H01L 24/20; H01L 23/3107; H01L 23/36; H01L 24/24; H01L 24/19; H01L 24/32; H01L 24/73; H01L 24/97; H01L 25/167; H01L 2224/19; H01L 2224/215; H01L 2224/24151; H01L 2224/32221; H01L 2224/73267; H01L 2224/95001

(57) ABSTRACT

A chip-on-film (COF) package includes a semiconductor chip comprising a plurality of external connection pads for connecting to outside of the semiconductor chip; a conductive portion electrically connected to the plurality of external connection pads; a base film attached to a lower end of the conductive portion and having an upper surface and a lower surface opposite each other; and a protective layer covering the conductive portion on the upper surface of the base film. The protective layer covers sidewalls and a lower surface of the semiconductor chip, and the conductive portion comprises a plurality of conductive lines disposed on the upper surface of the base film, and a plurality of via structures formed integrally with the plurality of conductive lines and electrically connected to the plurality of external connection pads.

### CROSS-REFERENCE TO RELATED APPLICATION

This application is based on and claims priority under 35 U.S.C. § 119 to Korean Patent Application No. 10-2023-0178741, filed on Dec. 11, 2023, in the Korean Intellectual Property Office, the disclosure of which is incorporated by reference herein in its entirety.

### BACKGROUND

Aspects of the inventive concept relate to a chip-on-film (COF) package and a display apparatus including the same.

A COF package may include a semiconductor chip mounted on a base film. The mounted semiconductor chip may be electrically connected to an external device through a conductive line on the base film. As recent display apparatuses require smaller bezels and thinner panels, there is an increasing need for process optimization technology and technology for controlling the temperature of semiconductor chips mounted on COF packages.

### SUMMARY

Aspects of the inventive concept provide a chip-on-film (COF) package with improved reliability.

Aspects of the inventive concept provide a display apparatus including a COF package with improved reliability.

According to an aspect of the inventive concept, a chip-on-film (COF) package includes a semiconductor chip comprising a plurality of external connection pads for connecting to outside of the semiconductor chip; a conductive portion electrically connected to the plurality of external connection pads; a base film attached to a lower end of the conductive portion and having an upper surface and a lower surface opposite each other; and a protective layer covering the conductive portion on the upper surface of the base film. The protective layer covers sidewalls and a lower surface of the semiconductor chip, and the conductive portion comprises a plurality of conductive lines disposed on the upper surface of the base film, and a plurality of via structures formed integrally with the plurality of conductive lines and electrically connected to the plurality of external connection pads.

According to another aspect of the inventive concept, a COF package includes a base film extending in a first direction and a second direction perpendicular to the first direction and including a semiconductor chip mounting area, a conductive layer disposed on an upper surface of the base film, a semiconductor chip mounted on the semiconductor chip mounting area and including a plurality of pads electrically connected to the conductive layer, a protective layer covering sidewalls and a lower portion of the semiconductor chip and covering the conductive layer on the upper surface of the base film so as to expose an upper surface of the semiconductor chip, and a heat dissipation member arranged to correspond to the semiconductor chip and including a conductive material. The conductive layer includes a conductive line disposed on the upper surface of the base film, and a via structure formed integrally with the conductive line without bonding and electrically connected to a pad of the plurality of pads, and in a plan view, a length of the heat dissipation member in the first direction is greater than a length of the semiconductor chip in the first direction, and a length of the heat dissipation member in the second direction is greater than a length of the semiconductor chip in the second direction.

According to another aspect of the inventive concept, a display apparatus includes a COF package including a base film having an upper surface and a lower surface opposite each other and extending in a first direction and a second direction perpendicular to the first direction, a display panel arranged to face a portion of the upper surface of the base film, and a driver printed circuit board arranged to face another portion of the upper surface of the base film, wherein the COF package includes a conductive portion disposed on the upper surface of the base film, a semiconductor chip including a plurality of pads electrically connected to the conductive portion, a protective layer covering the conductive portion so as to expose an upper surface of the semiconductor chip, and a heat dissipation member arranged to correspond to the semiconductor chip, the conductive portion includes a conductive line disposed on the upper surface of the base film, and a bump structure formed integrally with the conductive line without bonding and electrically connected to a pad of the plurality of pads, an upper surface of the protective layer is formed to be flat, a vertical level of the upper surface of the semiconductor chip is equal to a vertical level of the upper surface of the protective layer, and the protective layer includes solder resist or dry film resist, and in a plan view, a length of the heat dissipation member in the first direction is greater than a length of the semiconductor chip in the first direction, and a length of the heat dissipation member in the second direction is greater than a length of the semiconductor chip in the second direction.

### BRIEF DESCRIPTION OF THE DRAWINGS

Embodiments will be more clearly understood from the following detailed description taken in conjunction with the accompanying drawings in which:

FIG. 1 is a perspective view illustrating a display apparatus according to an embodiment;

FIG. 2 is a perspective view illustrating a chip-on-film (COF) package according to an embodiment;

FIG. 3 is a plan view illustrating the COF package of FIG. 2;

FIG. 4A is a side cross-sectional view illustrating a circuit area of the COF package of FIG. 2, according to an embodiment;

FIG. 4B is a side cross-sectional view illustrating a circuit area of the COF package of FIG. 2, according to another embodiment;

FIG. 5A is an enlarged side cross-sectional view of a region A of FIG. 4B, according to an embodiment;

FIG. 5B is an enlarged side cross-sectional view of the region A of FIG. 4B, according to another embodiment;

FIG. 6 is a plan view illustrating a COF package according to another embodiment;

FIG. 7 is a side cross-sectional view illustrating a circuit area of the COF package of FIG. 6;

FIGS. 8 and 9 are diagrams illustrating methods of manufacturing a COF package, according to an embodiment;

FIGS. 10 to 18 are diagrams illustrating a method of manufacturing a COF package, according to another embodiment;

FIG. 19A is a side cross-sectional view illustrating a display apparatus according to an embodiment;

FIG. 19B is a side cross-sectional view illustrating a display apparatus according to another embodiment; and

FIG. 20 is a side cross-sectional view illustrating a display apparatus according to another embodiment.

### DETAILED DESCRIPTION OF THE EMBODIMENTS

As the present embodiments allow for various changes and numerous forms, certain embodiments will be illustrated in the drawings and described in detail in the written description. However, this is not intended to limit the present embodiments to specific disclosed forms. In addition, embodiments described herein are merely examples, and various modifications may be made thereto from these embodiments.

The use of all illustrations or illustrative terms in the embodiments is simply to describe the technical ideas in detail, and the scope of the inventive concept is not limited by the illustrations or illustrative terms unless they are limited by claims.

Unless otherwise stated in the present specification, a vertical direction is defined as the Z direction and a first horizontal direction and a second horizontal direction may be defined as directions perpendicular to the Z direction. The first horizontal direction may be indicated by X and the second horizontal direction may be indicated by Y. A vertical level may refer to a height level in the vertical direction (Z) (e.g., a height above a particular reference point such as a top surface of a substrate or board). A horizontal width may refer to a length in the horizontal direction (X and/or Y) and a vertical length may refer to a length in the vertical direction (Z).

It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact. Other words used to describe the relationship between elements should be interpreted in a like fashion (e.g., “between” versus “directly between,” “adjacent” versus “directly adjacent,” etc.).

Terms such as “same,” “equal,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

Components described as thermally connected or in thermal communication are arranged such that heat will follow a path between the components to allow the heat to transfer from the first component to the second component. Simply because two components are part of the same device or package does not make them thermally connected. In general, components which are heat-conductive and directly connected to other heat-conductive or heat-generating components (or connected to those components through intermediate heat-conductive components or in such close proximity as to permit a substantial transfer of heat) will be described as thermally connected to those components, or in thermal communication with those components. On the contrary, two components with heat-insulative materials therebetween, which materials significantly prevent heat transfer between the two components, or only allow for incidental heat transfer, are not described as thermally connected or in thermal communication with each other. The terms “heat-conductive” or “thermally-conductive” do not apply to a particular material simply because it provides incidental heat conduction, but are intended to refer to materials that are typically known as good heat conductors or known to have utility for transferring heat, or components having similar heat conducting properties as those materials.

Spatially relative terms, such as “beneath,” “below,” “lower,” “above,” “upper,” “top,” “bottom,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

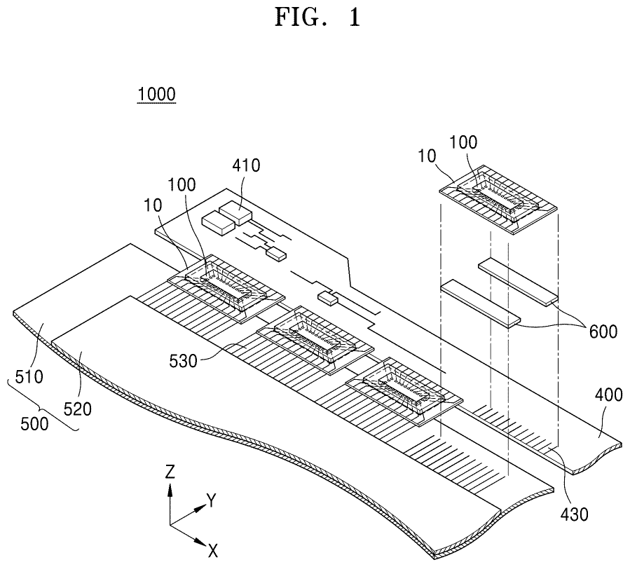

Referring to FIG. 1, a display apparatus 1000 may include at least one chip-on-film (COF) package 10, a driver printed circuit board 400, and a display panel 500.

The COF package 10 may be a package including a semiconductor chip 100, which is a display driver IC (DDI). In some embodiments, one semiconductor chip 100 may be arranged in one COF package 10. In other embodiments, different types of semiconductor chips 100 may be arranged in one COF package 10. For example, the semiconductor chip 100 may include a source driver chip and/or a gate driver chip. Though one semiconductor chip may be mentioned, a plurality of semiconductor chips 100 maybe included in the COF package. Items described in the singular herein may be provided in plural, as can be seen, for example, in the drawings. Thus, the description of a single item that is provided in plural should be understood to be applicable to the remaining plurality of items unless context indicates otherwise.

The COF package 10 may be arranged between the driver printed circuit board 400 and the display panel 500 and may be connected thereto. The COF package 10 may receive a signal output from the driver printed circuit board 400 and transmit the signal to the display panel 500.

One or more driver circuit chips 410 capable of simultaneously or sequentially applying power and signals to the COF package 10 may be mounted on the driver printed circuit board 400.

The display panel 500 may be, for example, a liquid crystal display (LCD) panel, a light-emitting diode (LED) panel, an organic LED (OLED) panel, a plasma display panel (PDP), or the like.

The COF package 10 may be electrically connected to each of a driver connection wiring 430 of the driver printed circuit board 400 and a panel connection wiring 530 of the display panel 500.

In some embodiments, one COF package 10 may be connected between the driver printed circuit board 400 and the display panel 500. For example, when the display panel 500 is intended to provide a small-area screen, such as a mobile phone, or when the display panel 500 supports a relatively low resolution, the display apparatus 1000 may include one COF package 10.

In other embodiments, a plurality of COF packages 10 may be connected between the driver printed circuit board 400 and the display panel 500. For example, when the display panel 500 is intended to provide a large-area screen, such as a television, or when the display panel 500 supports a relatively high resolution, the display apparatus 1000 may include a plurality of COF packages 10.

The COF package 10 may be connected to only one side of the display panel 500. However, the inventive concept is not limited thereto. In some embodiments, one or more COF packages 10 may be connected to each of two or more sides of the display panel 500.

The display panel 500 may include a transparent substrate 510, an image area 520 formed on the transparent substrate 510, and a panel connection wiring 530. The transparent substrate 510 may be, for example, a glass substrate or a flexible substrate. A plurality of pixels of the image area 520 may be respectively connected to a plurality of panel connection wirings 530 and may operate according to signals provided by the semiconductor chip 100 mounted on the COF package 10.

The COF package 10 may have an input pad formed at one end and an output pad formed at the other end. The input pad and the output pad may be respectively connected to the driver connection wiring 430 of the driver printed circuit board 400 and the panel connection wiring 530 of the display panel 500 by an anisotropic conductive layer 600.

The anisotropic conductive layer 600 may be, for example, an anisotropic conductive film or an anisotropic conductive paste. The anisotropic conductive layer 600 may have a structure in which conductive particles are dispersed within an insulating adhesive layer. In addition, the anisotropic conductive layer 600 may have anisotropic electrical characteristics that allow an electric current to pass only in the electrode direction Z when connected, and insulate in the direction X between adjacent electrodes. When an adhesive is melted by applying heat and pressure to the anisotropic conductive layer 600, the conductive particles may be arranged and conducted between opposing electrodes, for example, between the input pad and the driver connection wiring 430 and between the output pad and the panel connection wiring 530, and the adhesive may be filled and insulated between adjacent electrodes.

Hereinafter, the COF package 10 included in the display apparatus 1000, according to an embodiment, is described in detail.

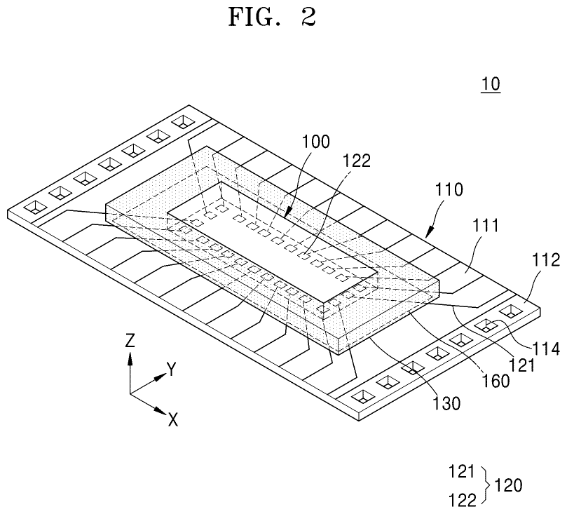

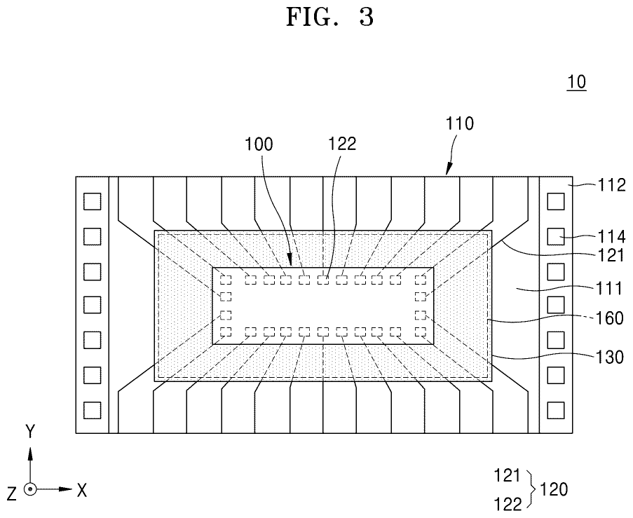

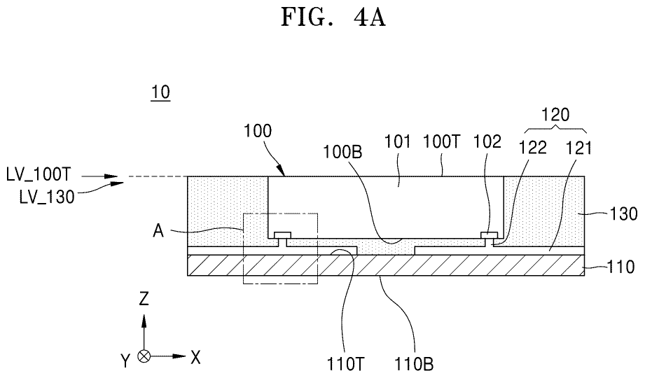

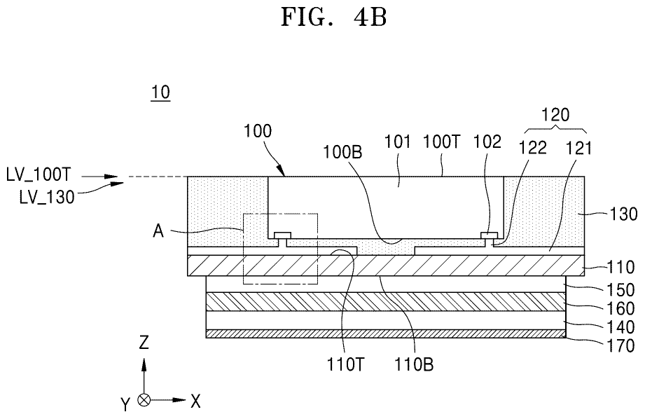

FIG. 2 is a perspective view illustrating the COF package 10 according to an embodiment. FIG. 3 is a plan view illustrating the COF package 10 of FIG. 2. FIG. 4A is a side cross-sectional view illustrating a circuit area of the COF package 10 of FIG. 2.

FIG. 4B is a side cross-sectional view illustrating the circuit area of the COF package 10 of FIG. 2, according to another embodiment.

Referring to FIGS. 2 to 4B together, the COF package 10 may include a semiconductor chip 100, a base film 110, a conductive portion 120, a heat dissipation member 160, and a protective layer 130.

The semiconductor chip 100 may be a DDI used to drive the display apparatus (see 1000 of FIG. 1). For example, the semiconductor chip 100 may be a source driver chip that generates an image signal by using a data signal transmitted from a timing controller and outputs the image signal to the display panel (see 500 of FIG. 1). Alternatively, the semiconductor chip 100 may be a gate driver chip that outputs a scan signal including a transistor on/off signal to the display panel (see 500 of FIG. 1).

However, the type of the semiconductor chip 100 is not limited thereto. For example, when the COF package 10 is connected to an electronic device other than the display apparatus (see 1000 of FIG. 1), the semiconductor chip 100 may be a chip that drives the electronic device.

For convenience of explanation, one semiconductor chip 100 is illustrated in the drawings, but the number of semiconductor chips 100 is not limited thereto. In some embodiments, due to the characteristics of the display apparatus (see 1000 of FIG. 1), the number of source driver chips may be equal to or greater than the number of gate driver chips.

In addition, the semiconductor chip 100 may have a long side in a first direction X and a short side in a second direction Y perpendicular to the first direction X. Therefore, the semiconductor chip 100 may have a rectangular shape. The length of the long side may be equal to or greater than about 1.5 times the length of the short side. The semiconductor chip 100 has the above-described shape so as to increase the degree of freedom in placement and design of a conductive line 121 included in the conductive portion 120 to be described below.

The semiconductor chip 100 may include a substrate 101 and a bump pad 102. In a cross-sectional view, two bump pads 102 are provided, but the number of bump pads 102 is not limited thereto. The substrate 101 is a semiconductor substrate and may have an active surface and an inactive surface opposite each other. Specifically, the substrate 101 may be a silicon (Si) wafer including or formed of crystalline silicon, polycrystalline silicon, or amorphous silicon. Alternatively, the substrate 101 may include or be formed of a semiconductor element, such as germanium (Ge), or a compound semiconductor, such as silicon carbide (SiC), gallium arsenide (GaAs), indium arsenide (InAs), and indium phosphide (InP).

In some embodiments, the substrate 101 may have a silicon-on-insulator (SOI) structure. In some embodiments, the substrate 101 may include a conductive area, for example, an impurity-doped well or an impurity-doped structure. In addition, the substrate 101 may have various device isolation structures, such as a shallow trench isolation (STI) structure.

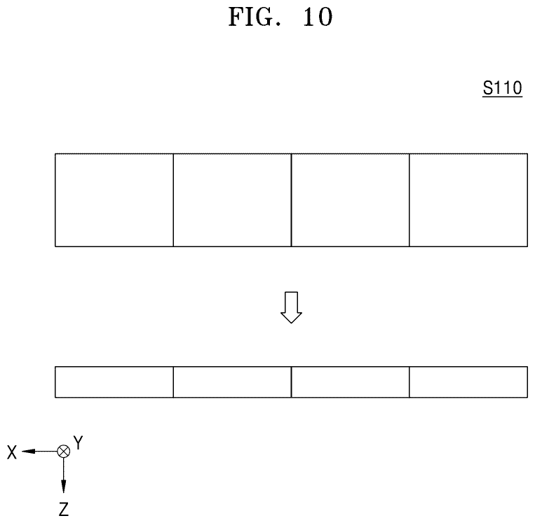

The semiconductor chip 100 may be arranged in a circuit area 111 of the base film 110, particularly in a chip mounting area (not shown). Generally, the semiconductor chip 100 may be mounted on the base film 110 through a flip chip bonding process. However, according to aspects of the inventive concept, the protective layer 130 may be formed to expose the upper surface of the semiconductor chip 100, and the conductive portion 120 may be formed by etching a portion of the protective layer 130. Details thereof are described below with reference to FIGS. 10 to 18. Thus, the semiconductor chip 100 may still be mounted in a flip chip manner, but without using the typical solder reflow bonding process.

The COF package 10 may include the conductive portion 120 disposed on the upper surface of the base film 110. The conductive portion 120 may include a conductive line 121 disposed on the upper surface of the base film 110, and a bump structure 122 formed integrally with the conductive line 121 without bonding, and electrically connected to the bump pad 102 of the semiconductor chip 100. The conductive portion 120 may include gold (Au), silver (Ag), nickel (Ni), tin (Sn), copper (Cu), or any alloy thereof. Because the conductive line 121 and the bump structure 122 are formed integrally with each other through a single process, the conductive line 121 and the bump structure 122 may include the same material, formed a as a single monolithic piece without grain boundaries therebetween. The bump structure 122 may be described as a conductive via, such as a through-protection-layer via, or more generally, a through-insulator via. The conductive portion 120 may be described as a conductive layer, for example, having a conductive line layer (or sub-layer) 121 and a conductive via layer (or sub-layer) 122. The conductive line layer 121 and conductive via layer 122 may be integrally formed.

The bump structure 122, may be disposed on the bump pad 102 exposed on the active surface of the semiconductor chip 100. The bump structure 122 may be formed integrally with the conductive line 121 and may be physically and electrically connected to the conductive line 121. The base film 110 may be attached to one side of the conductive line 121. A portion of the bump pad 102 may serve as an input terminal, and the remaining portion of the bump pad 102 may serve as an output terminal. The bump pad 102 may also be described generally as a connection pad, or an external connection pad, for connecting to an outside of the semiconductor chip 100.

The bump structure 122 may be arranged so that the bump pad 102 and the conductive line 121 contact each other and are electrically connected to each other. Through the bump structure 122, the semiconductor chip 100 may receive, from the outside, at least one of a control signal, a power signal, and a ground signal for the operation of the semiconductor chip 100, may receive, from the outside, a data signal to be stored in the semiconductor chip 100, or may provide, to the outside, data stored in the semiconductor chip 100. For example, the bump structure 122 may be a pillar structure, a column structure, or a via structure.

The base film 110 may be a flexible film including polyimide, which is a material with excellent coefficient of thermal expansion (CTE) and durability. However, the material of the base film 110 is not limited thereto. For example, the base film 110 may include or be formed of a synthetic resin, such as epoxy-based resin, acrylic, polyether nitrile, polyether sulfone, polyethylene terephthalate, or polyethylene naphthalate. The base film 110 may include a circuit area 111 at the center and perforation (PF) areas 112 on both side ends of the circuit area 111. The circuit area 111 may be an area where the semiconductor chip 100 is mounted. The base film 110 may have a thickness of 5 μm to 20 μm.

The PF areas 112 may be arranged on both side ends of the base film 110 and may include a plurality of PF holes 114. Reeling of the base film 110 onto a winding reel (not shown) and releasing of the base film 110 from the winding reel (not shown) may be controlled through the PF hole 114.

Because the pitch of the PF holes 114 is constant, the length of the base film 110 may be determined by the number of PF holes 114. On the other hand, the width and length of the base film 110 may be determined by the number and size of the semiconductor chips 100 mounted on the base film 110, the arrangement of the conductive lines 121 formed in the base film 110, etc.

The PF areas 112 may be cut before the COF package 10 is arranged in the display apparatus (see 1000 of FIG. 1). For example, in the COF package 10, only the circuit area 111 of the base film 110 may be arranged in the display apparatus (see 1000 of FIG. 1).

The conductive line 121 may be disposed on an upper surface 110T of the base film 110. The conductive line 121 may include, for example, aluminum foil or copper foil. In some embodiments, the conductive line 121 may be formed by patterning a metal layer formed on the base film 110 through casting, laminating, or electro-plating.

The conductive line 121 may be a portion of the conductive portion 120, and in some embodiments, may be plated with tin (Sb), gold (Au), nickel (Ni), or lead (Pb). The conductive line 121 may be electrically connected to the bump pad 102 of the semiconductor chip 100 while facing the bump pad 102 of the semiconductor chip 100. The conductive lines 121 connected to the bump pads 102 may be discontinuously apart from each other. The protective layer 130 may be formed in a space between the conductive lines 121.

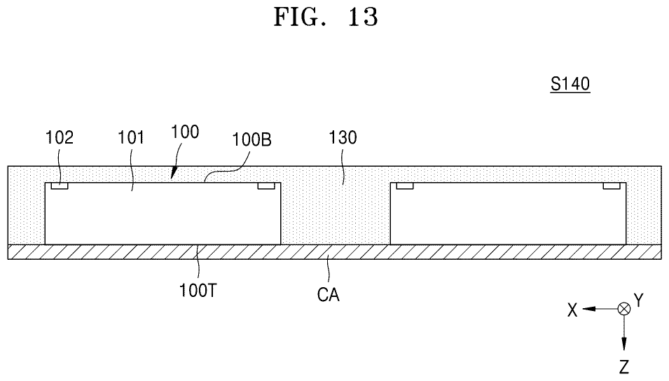

The protective layer 130 may be formed on the upper surface 110T of the base film 110 so as to protect the conductive portion 120 from external physical and/or chemical damage. The protective layer 130 may be formed before the base film 110 is attached thereto. The conductive portion 120 including the conductive line 121 and the bump structure 122 may be arranged in a recessed area of the protective layer 130. That is, after a portion of the protective layer 130 is etched, the conductive portion 120 may be deposited on the etched area of the protective layer 130 through sputtering. Accordingly, the protective layer 130 may be formed earlier than the base film 110 and the conductive portion 120. In order to protect the conductive line 121, the bump structure 122, and surroundings thereof from external physical and/or chemical damage, the protective layer 130 may be filled to cover the sidewalls and the lower surface of the semiconductor chip 100. For example, the protective layer 130 may cover the sidewalls and the lower portion of the semiconductor chip 100 on the upper surface of the base film 110 so as to expose the upper surface of the semiconductor chip 100. Accordingly, a vertical level LV_130 of the protective layer 130 may be equal to a vertical level LV_100T of the semiconductor chip 100. In addition, referring to FIG. 13, because the protective layer 130 is applied to cover a lower surface 100B of the semiconductor chip 100 when the semiconductor chip 100 is arranged upside down on a carrier CA, the vertical level LV_130 of the protective layer 130 may be constant and the upper surface of the protective layer 130 may be formed to be flat.

The protective layer 130 may include or be formed of, for example, solder resist or dry film resist. However, the inventive concept is not limited thereto. The protective layer 130 may include or be formed of a silicon oxide-based insulating layer or a silicon nitride-based insulating layer.

An adhesive layer 150 may be disposed on the lower surface 110B of the base film 110. The adhesive layer 150 may be classified into an inorganic adhesive and a polymer adhesive. Polymers may be largely classified into thermosetting resin and thermoplastic resin. The thermosetting resin has a three-dimensional (3D) cross-link structure after a monomer is heat-molded and does not soften even when reheated. In contrast, the thermoplastic resin is a resin that exhibits plasticity by heating and has a linear polymer structure. In some embodiments, the adhesive layer 150 may have a form of a tape, but the inventive concept is not limited thereto. The adhesive layer 150 may be thermally conductive, or may have a very thin thickness so that heat can pass through the adhesive layer 150 to be transferred between adjacent thermally conductive layers.

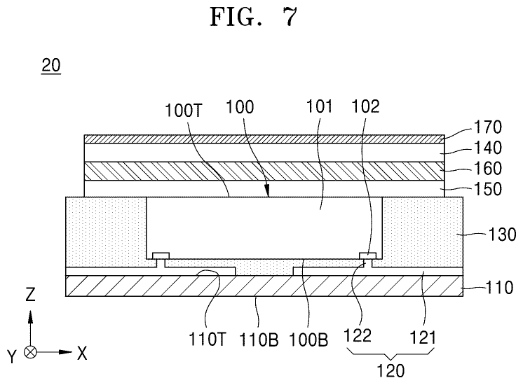

As recent display apparatuses require smaller bezels and thinner panels, there is an increasing need for technology for controlling the temperature of the semiconductor chip 100 mounted on the COF package 10. Accordingly, heat generated from the semiconductor chip 100 may be efficiently discharged to the outside of the COF package 10 through the heat dissipation member 160. The heat dissipation member 160 of one embodiment the inventive concept may be disposed below the semiconductor chip 100, as illustrated in FIG. 4B, or may be disposed above the semiconductor chip 100, as illustrated in FIG. 7. For example, in one embodiment, such as shown in FIG. 4B, the base film 110 may be vertically between the semiconductor chip 100 and the heat dissipation member 160. In another embodiment, such as shown in FIG. 7, the semiconductor chip 100 may be vertically between the base film 110 and the heat dissipation member 160. The heat dissipation member 160 may be described as a heat dissipation layer or a heat dissipation sheet.

FIG. 7 is a side cross-sectional view illustrating a circuit area of a COF package, according to another embodiment. The following description is given focusing on differences from FIG. 4B.

Referring to FIGS. 4B and 7, a heat dissipation member 160 may be arranged to correspond to a semiconductor chip 100. A distance between the semiconductor chip 100 and the heat dissipation member 160 is shorter when the heat dissipation member 160 is disposed above the semiconductor chip 100 than when the heat dissipation member 160 is disposed below the semiconductor chip 100. Above the semiconductor chip 100 and below the semiconductor chip 100 in the context of this embodiment refers to a bottom of the semiconductor chip 100 being where the bump pads 102 are located. As a distance between the heat dissipation member 160 and the semiconductor chip 100 decreases, heat dissipation characteristics may be improved. The heat dissipation member 160 may be disposed on the semiconductor chip 100. Because the length of the heat dissipation member 160 in the horizontal direction is greater than the length of the semiconductor chip 100 in the horizontal direction, the heat dissipation member 160 may extend onto an upper surface of a protective layer 130 (in the embodiment of FIG. 7) or onto a lower surface of the protective layer 130 (in the embodiment of FIG. 4B). In addition, because the length of the cover film 170 in the horizontal direction is greater than the length of the semiconductor chip 100 in the horizontal direction, the cover film 170 may extend onto the upper surface of the protective layer 130 to vertically overlap with and face the upper surface of the protective layer 130 (in the embodiment of FIG. 7) and may extend onto the lower surface of the protective layer 130 to vertically overlap with and face the lower surface of the protective layer 130 (in the embodiment of FIG. 4B).

The heat dissipation member 160 may be disposed on a lower surface of an adhesive layer 150 (in the embodiment of FIG. 4B) or on an upper surface of the adhesive layer 150 (in the embodiment of FIG. 7). The heat dissipation member 160 may be disposed on a lower surface 110B of a base film 110 corresponding to the semiconductor chip 100 (in the embodiment of FIG. 4B) or on an upper surface 110T of a base film 110 corresponding to semiconductor chip 100 (in the embodiment of FIG. 7) and may serve to dissipate heat emitted from the semiconductor chip 100. For efficient heat dissipation characteristics, the length of the heat dissipation member 160 in the first direction X may be greater than the length of the long side of the semiconductor chip 100, and the length of the heat dissipation member 160 in the second direction Y may be greater than the length of the short side of the semiconductor chip 100.

In some embodiments, the heat dissipation member 160 may be provided in a form of a tape formed of metal. The metal may be, for example, aluminum (Al), copper (Cu), or tungsten (W), but the inventive concept is not limited thereto. In other embodiments, the heat dissipation member 160 may include or be formed of epoxy, acrylic, silicon, etc. In order to obtain an excellent heat dissipation effect, the resin may include a thermally conductive filler. The thermally conductive filler may include alumina (Al₂O₃), boron nitride (BN), aluminum nitride (AlN), or diamond. In addition, the heat dissipation member 160 may include or be formed of a curable material. For example the heat dissipation member 160 may include or be formed of a resin capable of heat curing, room temperature curing, or ultraviolet (UV) curing.

The cover film 170 may be formed on the lower surface of the heat dissipation member 160 (in the embodiment of FIG. 4B) or on the upper surface of the heat dissipation member 160 (in the embodiment of FIG. 7) so as to protect the heat dissipation member 160 from external physical and/or chemical damage. The cover film 170 may be arranged to completely cover the heat dissipation member 160. The cover film 170 may include, for example, a synthetic resin, such as epoxy-based resin, acrylic, polyether nitrile, polyether sulfone, polyethylene terephthalate, or polyethylene naphthalate. A cover adhesive layer 140 may be arranged between the heat dissipation member 160 and the cover film 170. The cover adhesive layer 140 may include substantially the same material as the adhesive layer 150. In addition, the adhesive layer 150 may have a form of an adhesive tape, but the inventive concept is not limited thereto.

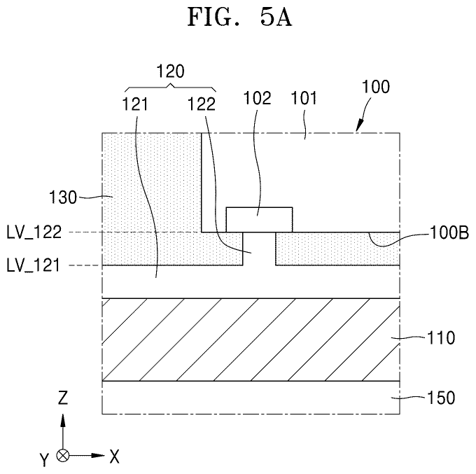

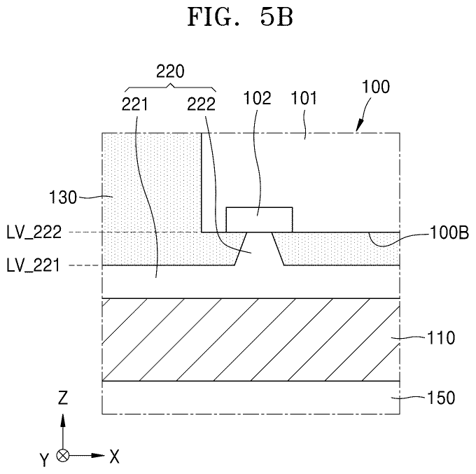

FIG. 5A is an enlarged side cross-sectional view of a region A of FIG. 4B, according to an embodiment.

Referring to FIG. 5A, a protective layer 130 may be formed to cover sidewalls and a lower surface of a substrate 101 included in a semiconductor chip 100. In addition, the protective layer 130 may cover at least a portion of a bump pad 102. A conductive portion 120 including a conductive line 121 and a bump structure 122 may be formed in the lower portion of the semiconductor chip 100.

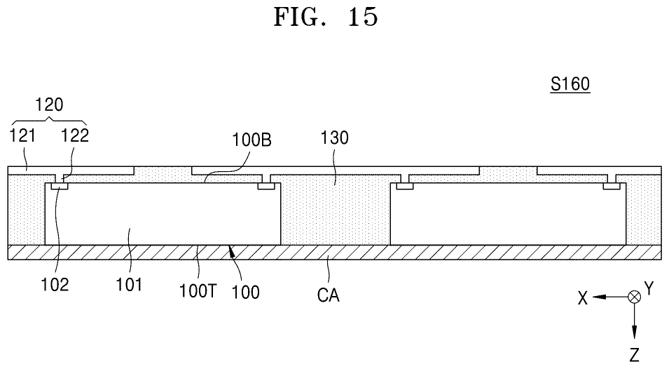

The conductive line 121 and the bump structure 122 may be deposited in a region from which the protective layer (see 130 of FIG. 4B) is partially removed. A vertical level LV_122 of a top of the bump structure 122 may be higher than a vertical level LV_121 of the top of conductive line 121. More specifically, referring to FIG. 15 together with FIG. 5A, the bump structure 122 may be deposited to extend from the vertical level LV_122 of the bump structure 122 to the vertical level LV_121 of the conductive line 121 through a sputtering process. The conductive line 121 may be deposited to extend from the vertical level LV_121 of the conductive line 121 to an upper surface of a base film 110 through a sputtering process. Because the conductive line 121 and the bump structure 122 are formed in a single process through a process such as a patterning-type sputtering deposition, the conductive line 121 and the bump structure 122 may be formed integrally with each other. Accordingly, a bonding process of attaching the bump structure 122 to the conductive line 121, which is commonly performed, may be omitted.

The bump structure 122 and the conductive line 121 may have different thicknesses in the vertical direction, but may be formed to have the same thickness depending on process conditions. The bump structure 122 may have a constant width in the horizontal direction. The bump structure 122 may have a molded shape, for example, having straight side surfaces that conform to the shape of a side wall of the protective layer 130. Although not illustrated, the horizontal cross-section of the bump structure 122 may be formed in a circular shape as well as a polygonal shape including a rectangular shape. The thicknesses of the bump structure 122 and the conductive line 121 in the vertical direction may be determined according to the thickness of the area where the protective layer 130 is etched.

FIG. 5B is an enlarged side cross-sectional view of the region A of FIG. 4B, according to another embodiment. In FIG. 5B, differences from FIG. 5A are mainly described.

Referring to FIG. 5B, a conductive portion 220 may include a conductive line 221 and a bump structure 222.

The conductive line 221 in FIG. 5B may correspond to the conductive line 121 in FIG. 5A. The width of the bump structure 122 in the horizontal direction may not be constant. More specifically, the bump structure 222 may be formed in a tapered shape in which a width in the horizontal direction becomes narrower as a distance to a lower surface 100B of a semiconductor chip 100 decreases. The shape of the bump structure 222 may correspond to an area where the protective layer (see 130 of FIG. 4B) is etched, and thus, as described above, the bump structure 222 may have a molded shape, conforming to a shape of a sidewall of the protective layer 130. An inclined angle of the bump structure 222 is not limited to the illustrated shape and may be formed differently depending on a shape of the semiconductor chip 100, a thickness of a base film 110, and a type of process.

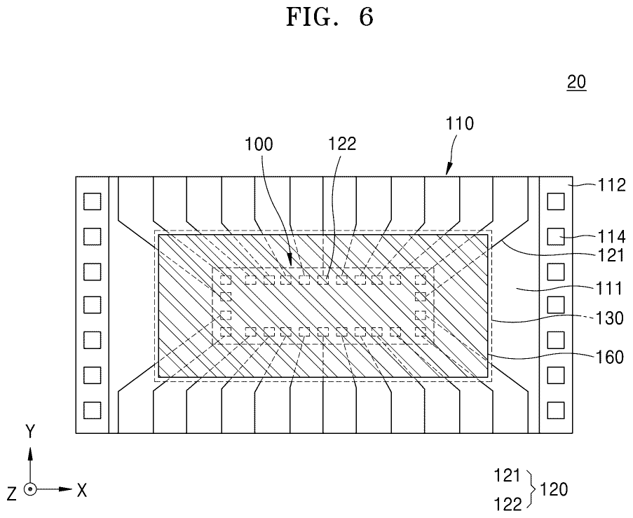

FIG. 6 is a plan view illustrating a COF package 20 according to another embodiment. FIG. 7 is a side cross-sectional view illustrating a circuit area of the COF package 20 of FIG. 6. Hereinafter, differences from FIGS. 2 to 4B are mainly described, and some of the above discussion above made in connection with FIG. 7 may be repeated.

Referring to FIGS. 6 and 7, the COF package 20 may include a heat dissipation member 160, an adhesive layer 150, a cover adhesive layer 140, and a cover film 170. The heat dissipation member 160 may be disposed on a semiconductor chip 100. The adhesive layer 150 may be arranged between the upper surface of the semiconductor chip 100 and the heat dissipation member 160. The cover film 170 may be attached to the upper portion of the heat dissipation member 160. The cover adhesive layer 140 may be arranged between the cover film 170 and the heat dissipation member 160. The cover adhesive layer 140 may include the same material as the adhesive layer 150.

FIG. 6 is a plan view in which the cover film 170 attached to the upper surface of the heat dissipation member 160 in FIG. 7 is omitted, for ease of viewing other components. Accordingly, when viewed above, only the heat dissipation member 160 covering the upper surface of the semiconductor chip 100 and a portion of the protective layer 130 is illustrated.

The length of the heat dissipation member 160 in the first direction X may be shorter than the length of the protective layer 130 extending in the first direction X. The length of the heat dissipation member 160 in the second direction Y may be shorter than the length of the protective layer 130 extending in the second direction Y. The length of the heat dissipation member 160 in the first direction X may be longer than the length of the semiconductor chip 100 in the first direction X. The length of the heat dissipation member 160 in the second direction Y may be longer than the length of the semiconductor chip 100 in the second direction Y. Accordingly, the heat dissipation member 160 may be formed to completely overlap the upper surface of the semiconductor chip 100. It should be noted that these same relative lengths are depicted in FIG. 4B in connection with the embodiment of FIG. 4B.

As described with reference to FIGS. 4A and 4B, the vertical level of the upper surface of the protective layer 130 may be formed to be equal to the vertical level of the upper surface 100T of the semiconductor chip, and the upper surface of the protective layer 130 may be formed to be flat. Accordingly, the adhesive layer 150 may be disposed evenly on the upper surface of the semiconductor chip 100 and the upper portion of the protective layer 130, and the same applies to the heat dissipation member 160 and the cover film 170 attached to the upper portion of the adhesive layer 150. In the embodiment of FIGS. 6 and 7, the adhesive layer 150 is directly between the heat dissipation member 160 and the top surface 100T of the semiconductor chip 100, and is directly between the heat dissipation member 160 and a top surface of the protective layer 130. In the embodiment of FIG. 4B, the adhesive layer 150 is directly between the heat dissipation member 160 and the bottom surface 110B of the base film 110.

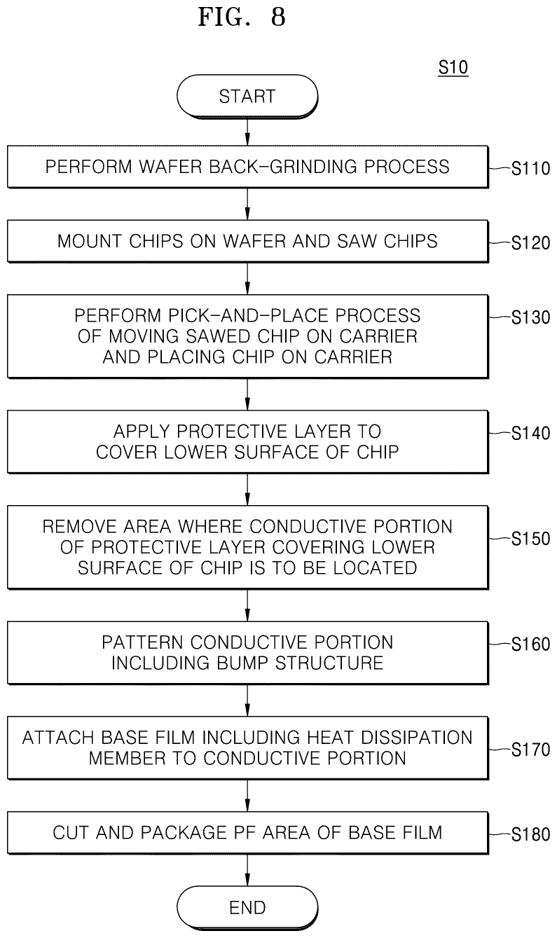

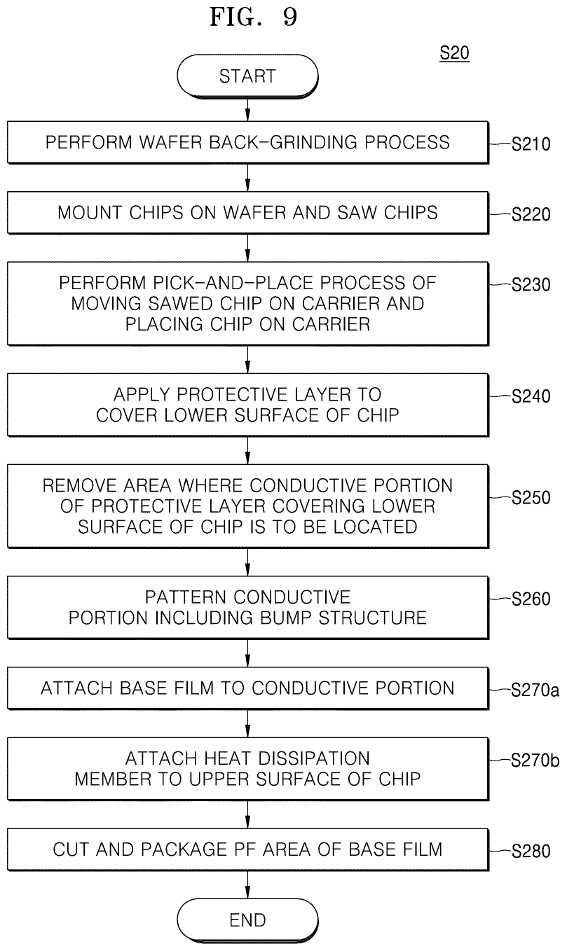

FIGS. 8 and 9 are diagrams illustrating methods of manufacturing a COF package, according to an embodiment.

When a certain embodiment may be implemented differently, a specific process order may be performed differently from the described order. For example, two consecutively described processes may be performed substantially at the same time or performed in an order opposite to the described order. The chips described with reference to FIGS. 8 and 9 may correspond to the semiconductor chips 100 illustrated in FIGS. 1 to 7.

Referring to FIG. 8, a method S10 of manufacturing a COF package may include process sequences of first to eighth operations S110 to S180.

The method S10 of manufacturing the COF package, according to the inventive concept, may include the first operation S110 that is a back-grinding process of grinding a back side of a wafer, the second operation S120 of mounting chips on the wafer and sawing the chips, the third operation S130 that is a pick-and-place process of moving the sawed chip on a carrier and placing the chip on the carrier, the fourth operation S140 of applying a protective layer to cover the lower surface of the chip located on the carrier, the fifth operation S150 of removing an area where a conductive portion of the protective layer covering the lower surface of the chip is to be located, the sixth operation S160 of patterning the conductive portion including a bump structure, the seventh operation S170 of attaching a base film including a heat dissipation member to the conductive portion, and the eighth operation S180 of cutting and packaging a PF area of the base film.

In FIG. 9, a method S20 of manufacturing a COF package may include process sequences of first to ninth operations S210 to S280. The first to sixth operations S210 to S260 of FIG. 9 may respectively correspond to the first to sixth operations S110 to S160 of FIG. 8. The ninth operation S280 in FIG. 9 may correspond to the eighth operation S180 in FIG. 8.

The method S20 of manufacturing the COF package may include the seventh operation S270a of attaching a base film to a conductive portion and the eighth operation S270b of attaching a heat dissipation member to the upper surface of the chip. Accordingly, the seventh operation S270a and the eighth operation S270b of FIG. 9 differ from the seventh operation S170 of FIG. 8 in that the seventh operation S170 of FIG. 8 is divided into two operations and the heat dissipation member is attached to the upper surface of the chip rather than the lower surface of the chip.

FIGS. 10 to 18 are diagrams illustrating a method of manufacturing a COF package, according to another embodiment.

FIG. 10 is a diagram illustrating the first operation S110 of FIG. 8. A wafer (not shown) may be formed to be thin by grinding the bottom of the wafer (not shown). The wafer (not shown) may become a substrate 101 on which a semiconductor chip (see 100 of FIG. 4A) is to be formed.

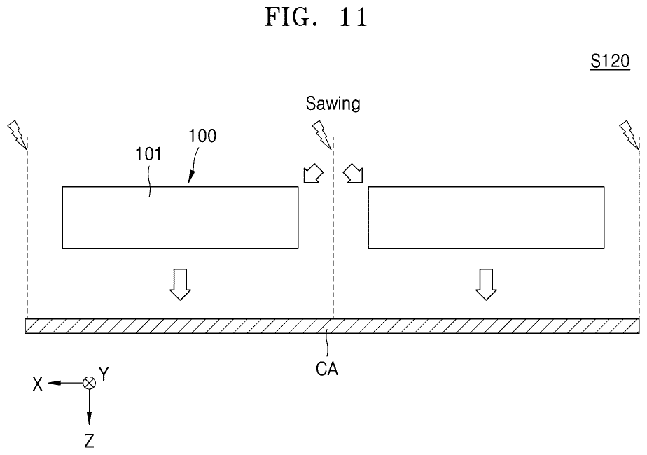

FIG. 11 is a diagram illustrating the second operation S120 of FIG. 8. The semiconductor chip 100 may be mounted on the ground wafer (not shown), and the mounted wafer (not shown) may be sawed into a plurality of semiconductor chips 100 through a sawing process. The sawing process may use a physical saw or a laser. Two separate semiconductor chips 100 are illustrated in FIG. 11, but the number of semiconductor chips 100 is not limited thereto. The semiconductor chip 100 may include the substrate 101. Because the semiconductor chip 100 is placed upside down on a carrier CA, the upper surface of the semiconductor chip may be in contact with the carrier CA and the lower surface of the semiconductor chip may be exposed.

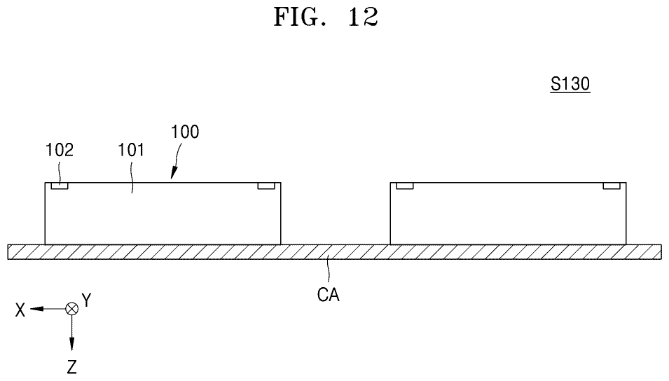

FIG. 12 is a diagram illustrating the third operation S130 of FIG. 8. The sawed semiconductor chips 100 may be individually picked and placed on the upper surface of the carrier CA. A bump pad 102 described above may be formed on a surface of the semiconductor chip 100 opposite to the surface of the semiconductor chip 100 facing the carrier CA. That is, the bump pad 102 may be formed on the lower surface of the semiconductor chip 100. The number of bump pads 102 is not limited to the illustrated number.

FIG. 13 is a diagram illustrating the fourth operation S140 of FIG. 8. A protective layer 130 may be applied to cover the lower surface 100B of the semiconductor chip. In addition, the protective layer 130 may cover the sidewalls of the semiconductor chip 100. Because the upper surface 100T of the semiconductor chip is attached to the carrier CA, the upper surface 100T of the semiconductor chip is not covered with the protective layer 130. The protective layer 130 may be applied to form a uniform height.

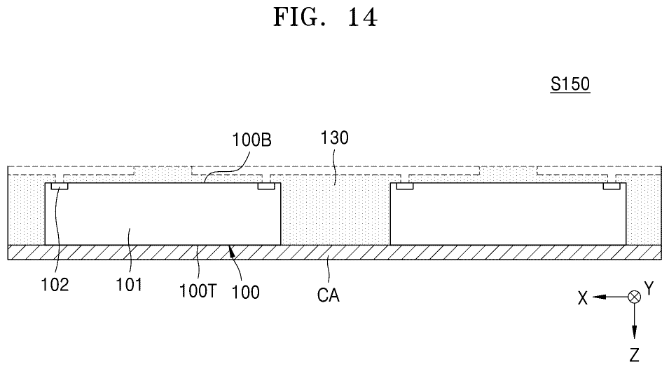

FIG. 14 is a diagram illustrating the fifth operation S150 of FIG. 8. A removing process may be performed on a portion of the protective layer 130. The removing process may be an etching process. An area from which the protective layer 130 is removed is indicated by a dashed line. The area indicated by the dashed line may correspond to an area where the conductive part is to be formed. A portion of the area may be formed to expose a portion of the bump pad 102. The lower surface 100B of the semiconductor chip may be covered with the protective layer 130, and the protective layer 130 corresponding to the lower surface 100B of the semiconductor chip may not be removed.

FIG. 15 is a diagram illustrating the sixth operation S160 of FIG. 8. In FIG. 14, the conductive portion 120 may be formed by performing a patterning process on the area from which the protective layer 130 has been removed. The patterning process may be a deposition process. More specifically, the patterning process may be a sputtering process of depositing metal, or other process that does not use compression or does not require reflow, and thus does not require a heating process, or uses lower temperature heating than a heat compression bonding or reflow bonding process.

The conductive portion 120 may include a bump structure 122 in contact with the bump pad 102, and a conductive line 121 formed integrally with the bump structure 122. The surface of the conductive line 121 opposite to the surface of the conductive line 121 facing the semiconductor chip 100 may be formed uniformly. The thickness and shape of the conductive portion 120 may be formed differently depending on a process and are not limited to those illustrated in the drawings.

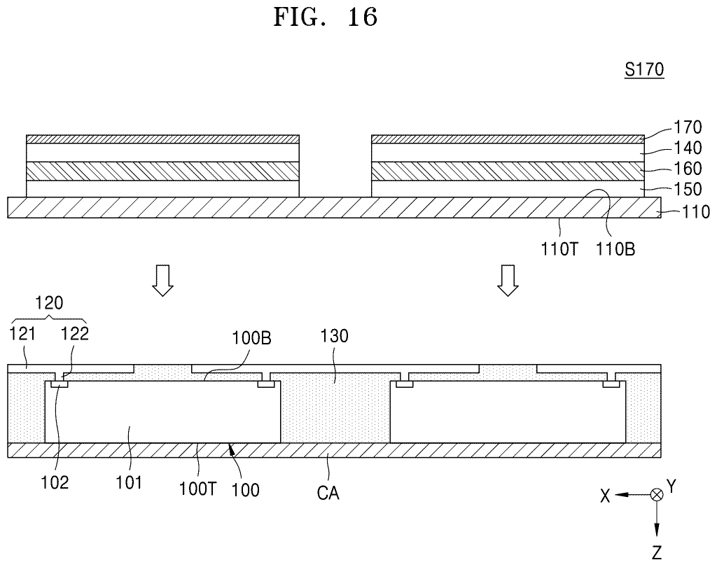

FIG. 16 is a diagram illustrating the seventh operation S170 of FIG. 8. A base film 110 may be attached to the conductive portion 120. The upper surface 110T of the base film may be in physical contact with the conductive portion 120. A heat dissipation member 160 including an adhesive layer 150 may be attached to the lower surface 110B of the base film. Accordingly, the base film 110 including the heat dissipation member 160 may be attached to the conductive portion 120.

A cover film 170 may be attached to the heat dissipation member 160. A cover adhesive layer 140 may be arranged between the heat dissipation member 160 and the cover film 170.

The COF package 10 of FIG. 4B may be formed by performing the eighth operation S180 of FIG. 8 to attach the base film 110 including the heat dissipation member 160 to the conductive portion 120, remove the carrier CA, rotate 180 degrees around the Y-axis, and cut and package the PF area of the base film 110.

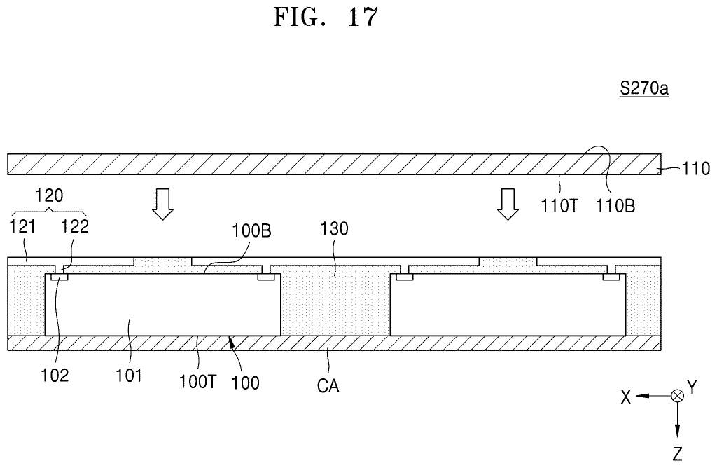

FIG. 17 is a diagram illustrating the seventh operation S270a of FIG. 9. The base film 110 may be attached to the conductive portion 120. The upper surface 110T of the base film may be in physical contact with the conductive portion 120.

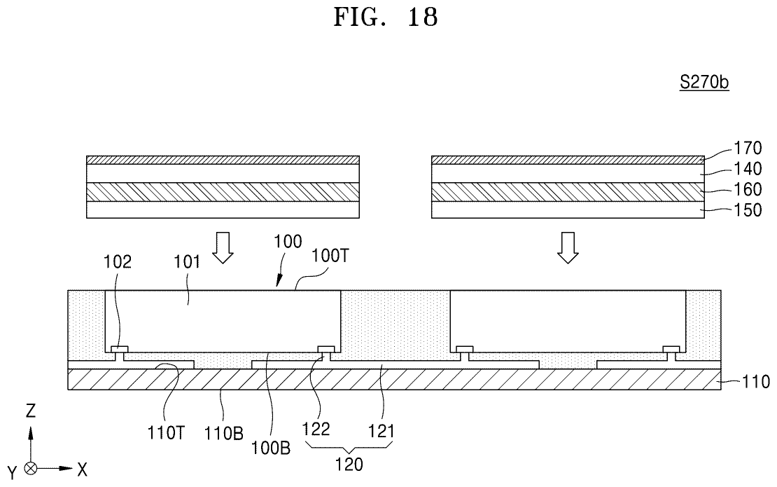

FIG. 18 is a diagram illustrating the eighth operation S270b of FIG. 9. In FIG. 18, the carrier CA may be removed, and the semiconductor chip may be rotated 180 degrees around the Y-axis so that the upper surface 100T of the semiconductor chip faces upward. Thereafter, the heat dissipation member 160 may be attached to the upper surface 100T of the semiconductor chip. An adhesive layer 150 may be arranged between the heat dissipation member 160 and the upper surface 100T of the semiconductor chip.

Thereafter, the COF package 20 of FIG. 7 may be formed by performing the ninth operation S280 of FIG. 9 to cut and package the PF area of the base film 110.

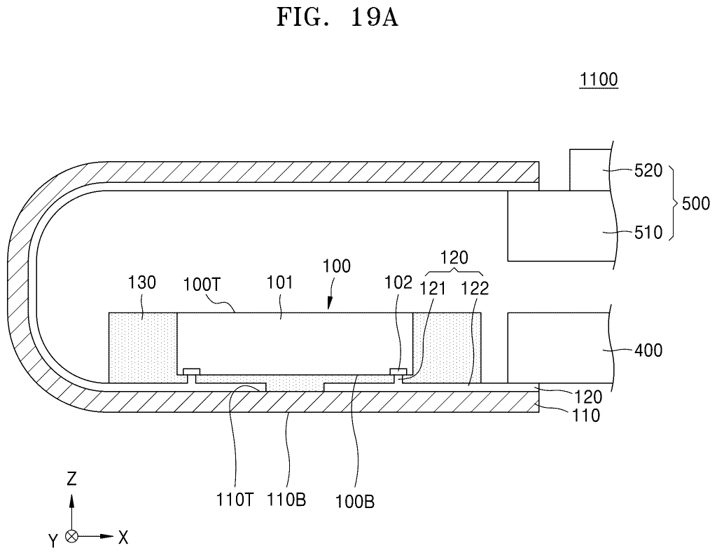

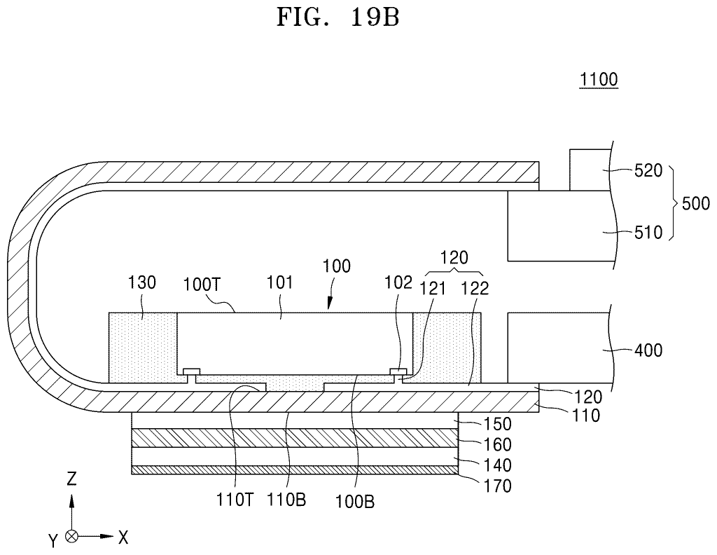

FIG. 19A is a side cross-sectional view illustrating a display apparatus according to an embodiment.

FIG. 19B is a side cross-sectional view illustrating a display apparatus according to another embodiment.

FIGS. 19A and 19B respectively illustrate display apparatuses 1100 and 1100′ each including a COF package 10, a driver printed circuit board 400, and a display panel 500.

In the display apparatus 1100 according to an embodiment, a display panel 500 may include a transparent substrate 510 and an image area 520 formed on the transparent substrate 510. FIGS. 19A and 19B illustrate a state in which a portion of the COF package 10 described with reference to FIGS. 2 to 4A is bent, but the inventive concept is not limited thereto.

In the display apparatus 1100′ according to an embodiment, the display panel 500 may include a transparent substrate 510 and an image area 520 formed on the transparent substrate 510. FIGS. 19A and 19B illustrate a state in which a portion of the COF package 10 described with reference to FIGS. 2 to 4B is bent, but the inventive concept is not limited thereto.

One end portion of the COF package 10 and a portion of the display panel 500 may be arranged to face each other, and the other end portion of the COF package 10 and a portion of the driver printed circuit board 400 may be arranged to face each other. The COF package 10 may receive a signal output from the driver printed circuit board 400 through the conductive line 121 and transmit the signal to the display panel 500 through the conductive portion 120.

One or more driver circuit chips (see 410 of FIG. 1) capable of simultaneously or sequentially applying power and signals to the COF package 10 through the conductive portion 120 may be mounted on the driver printed circuit board 400.

The display panel 500 may include a transparent substrate 510 and an image area 520 including a plurality of pixels. The transparent substrate 510 may have a front surface and a back surface opposite each other, and the image area 520 may be disposed on the front surface of the transparent substrate 510. The COF package 10 may be bent and fixed to the front surface of the transparent substrate 510, and the driver printed circuit board 400 may be arranged to face the rear surface of the transparent substrate 510.

The COF package 10 may be bent and fixed to the front surface of the display panel 500, and the driver printed circuit board 400 may be arranged to face the rear surface of the display panel 500.

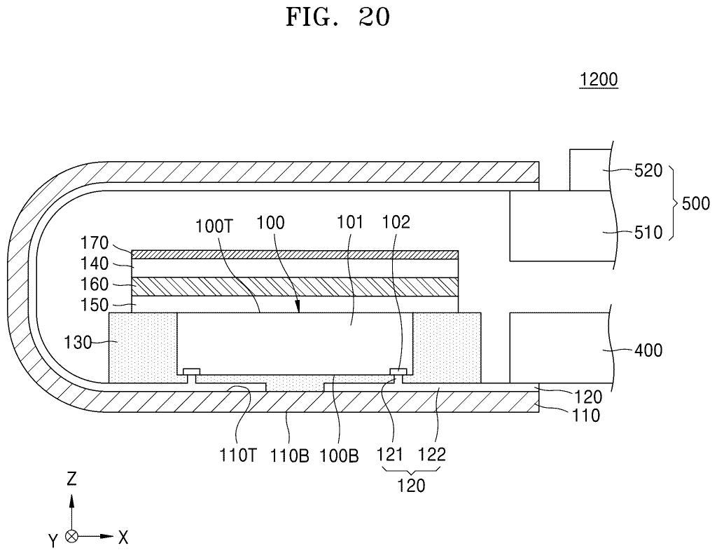

FIG. 20 is a side cross-sectional view illustrating a display apparatus 1200 according to another embodiment.

In the display apparatus 1200 according to an embodiment, a display panel 500 may include a transparent substrate 510 and an image area 520 formed on the transparent substrate 510. FIG. 20 illustrates a state in which a portion of the COF package 20 described with reference to FIGS. 6 and 7 is bent, but the inventive concept is not limited thereto. Because all other areas are the same as those in FIGS. 19A and 19B, descriptions thereof are omitted.

While the inventive concept has been particularly shown and described with reference to embodiments thereof, it will be understood that various changes in form and details may be made therein without departing from the spirit and scope of the following claims.

What is claimed is:

1. A chip-on-film (COF) package comprising:
a semiconductor chip comprising a plurality of external connection pads for connecting to outside of the semiconductor chip;
a conductive portion electrically connected to the plurality of external connection pads;
a base film attached to a lower end of the conductive portion and having an upper surface and a lower surface opposite each other; and
a protective layer covering the conductive portion on the upper surface of the base film,
wherein the protective layer covers sidewalls and a lower surface of the semiconductor chip, and
wherein the conductive portion comprises:
a plurality of conductive lines disposed on the upper surface of the base film; and
a plurality of via structures formed integrally with the plurality of conductive lines and electrically connected to the plurality of external connection pads.

2. The COF package of claim 1, wherein a vertical level of an upper surface of the semiconductor chip is equal to a vertical level of an upper surface of the protective layer.

3. The COF package of claim 1, further comprising a heat dissipation member arranged on the semiconductor chip,
wherein the heat dissipation member comprises a metal layer including a heat-conductive material.

4. The COF package of claim 3, wherein the heat dissipation member is disposed below the semiconductor chip, and
wherein the COF package further comprises:
an adhesive layer between the lower surface of the base film and the heat dissipation member; and
a cover film attached to a lower portion of the heat dissipation member.

5. The COF package of claim 3, wherein the heat dissipation member is disposed above the semiconductor chip, and
the COF package further comprises:
an adhesive layer between an upper surface of the semiconductor chip and the heat dissipation member; and
a cover film attached to an upper portion of the heat dissipation member.

6. The COF package of claim 3, wherein, when a direction parallel to an axis along which a long side of the semiconductor chip extends is defined as a first direction and a direction parallel to an axis through which a short side of the semiconductor chip extends is defined as a second direction, and
wherein in a plan view, a length of the heat dissipation member in the first direction is greater than a length of the semiconductor chip in the first direction and a length of the heat dissipation member in the second direction is greater than a length of the semiconductor chip in the second direction.

7. The COF package of claim 1, wherein:
a vertical level of each via structure is higher than a vertical level of each conductive line, and
the conductive portion is arranged in a recessed area of the protective layer.

8. The COF package of claim 1, wherein:
the conductive portion includes gold (Au), silver (Ag), nickel (Ni), tin (Sn), copper (Cu), or any alloy thereof, and
the conductive lines and the via structures include the same material.

9. The COF package of claim 1, wherein:
the base film has a thickness of 5 μm to 20 μm, and
the base film is a flexible film including polyimide.

10. A chip-on-film (COF) package comprising:
a base film extending in a first direction and a second direction perpendicular to the first direction and comprising a semiconductor chip mounting area;
a conductive layer disposed on an upper surface of the base film;
a semiconductor chip mounted on the semiconductor chip mounting area and comprising a plurality of pads electrically connected to the conductive layer;
a protective layer covering sidewalls and a lower portion of the semiconductor chip and covering the conductive layer on the upper surface of the base film so as to expose an upper surface of the semiconductor chip; and
a heat dissipation member arranged to correspond to the semiconductor chip and including a heat-conductive material,
wherein the conductive layer comprises:
a conductive line disposed on the upper surface of the base film; and
a via structure formed integrally with the conductive line without bonding and electrically connected to a pad of the plurality of pads, and
in a plan view, a length of the heat dissipation member in the first direction is greater than a length of the semiconductor chip in the first direction and a length of the heat dissipation member in the second direction is greater than a length of the semiconductor chip in the second direction.

11. The COF package of claim 10, wherein:
an upper surface of the protective layer is formed to be flat,
a vertical level of the upper surface of the semiconductor chip is equal to a vertical level of the upper surface of the protective layer, and
the protective layer includes solder resist or dry film resist.

12. The COF package of claim 10, wherein:
the heat dissipation member is disposed below the semiconductor chip, and
the COF package further comprises:
an adhesive layer between a lower surface of the base film and the heat dissipation member; and
a cover film attached to a lower portion of the heat dissipation member.

13. The COF package of claim 10, further comprising:
an adhesive layer between an upper surface of the semiconductor chip and the heat dissipation member; and
a cover film attached to an upper portion of the heat dissipation member,
wherein the heat dissipation member is disposed above the semiconductor chip, and
wherein the heat dissipation member and the cover film extend onto an upper surface of the protective layer.

14. The COF package of claim 10, wherein the via structure has a tapered shape in which a width in a horizontal direction becomes narrower as a distance to a lower surface of the semiconductor chip decreases.

15. The COF package of claim 10, wherein:
a vertical level of the via structure is higher than a vertical level of the conductive line, and
the conductive layer is arranged in a recessed area of the protective layer.

16. The COF package of claim 10, wherein:
the conductive layer includes gold (Au), silver (Ag), nickel (Ni), tin (Sn), copper (Cu), or any alloy thereof, and
the conductive line and the via structure include the same material.

17. A display apparatus comprising:
a chip-on-film (COF) package comprising a base film having an upper surface and a lower surface opposite each other and extending in a first direction and a second direction perpendicular to the first direction;
a display panel arranged to face a portion of the upper surface of the base film; and
a driver printed circuit board arranged to face another portion of the upper surface of the base film,
wherein the COF package comprises:
a conductive portion disposed on the upper surface of the base film;
a semiconductor chip comprising a plurality of pads electrically connected to the conductive portion;
a protective layer covering the conductive portion so as to expose an upper surface of the semiconductor chip; and
a heat dissipation member arranged to correspond to the semiconductor chip,
wherein the conductive portion comprises:
a conductive line disposed on the upper surface of the base film; and
a via structure formed integrally with the conductive line without bonding and electrically connected to a pad of the plurality of pads,
wherein an upper surface of the protective layer is formed to be flat,
wherein a vertical level of the upper surface of the semiconductor chip is equal to a vertical level of the upper surface of the protective layer, and
wherein the protective layer includes solder resist or dry film resist, and
wherein in a plan view, a length of the heat dissipation member in the first direction is greater than a length of the semiconductor chip in the first direction and a length of the heat dissipation member in the second direction is greater than a length of the semiconductor chip in the second direction.

18. The display apparatus of claim 17, wherein:
the base film is a flexible film including polyimide.
the display panel has a front surface, on which a plurality of pixels are provided, and a back surface opposite to the front surface,
the COF package is bent and fixed to the front surface of the display panel, and
the driver printed circuit board is arranged to face the back surface of the display panel.

19. The display apparatus of claim 17, wherein:
the heat dissipation member is disposed below the semiconductor chip, and
the COF package further comprises:
an adhesive layer between the lower surface of the base film and the heat dissipation member; and
a cover film attached to a lower portion of the heat dissipation member.

20. The display apparatus of claim 17, wherein:
the heat dissipation member is disposed above the semiconductor chip, and
the display apparatus further comprises:
an adhesive layer between the upper surface of the semiconductor chip and the heat dissipation member; and
a cover film attached to an upper portion of the heat dissipation member.
